(19) United States
(12) Patent Application Publication
(10) Pub. No.: US 2007/0200238 A1
(43) Pub. Date: Aug. 30, 2007

(54) Semiconductor integrated circuit apparatus and method of designing the same

(76) Inventors: Tomoaki Ikegami, Osaka (JP); Hidetoshi Nishimura, Osaka (JP)

Correspondence Address: MCDERMOTT WILL & EMERY LLP, 600 13TH STREET, NW, WASHINGTON, DC, 20005-3096, US

(21) Appl. No.: 11/703,626

(22) Filed: Feb. 8, 2007

(30) Foreign Application Priority Data
Feb. 28, 2006 (JP) 2006-053128

(51) Int. Cl. H01L 23/48

(52) U.S. Cl. 257/734

(57) ABSTRACT

In a semiconductor integrated circuit apparatus formed by a core cell constituting a circuit function and a power wiring cell including a power wiring, a metal of a power wiring unit cell constituting the power wiring cell is formed to take a shape of T, and the power wiring unit cell is disposed adjacently, thereby forming a serial power wiring. The core cell and the power wiring cell are connected to each other through a metal wiring in the core cell in which coordinates in a horizontal direction are preset, and a power signal is thus supplied.

### BACKGROUND OF THE INVENTION

1. Field of the Invention

The present invention relates to a semiconductor integrated circuit apparatus and a method of designing the same, and more particularly to a power wiring structure in a logic cell and a designing method.

2. Description of the Related Art

In recent years, referring to a semiconductor device to be loaded into a semiconductor integrated circuit apparatus, a demand for a reduction in an area of a standard logic cell has been increased more and more with a microfabrication, while the number of gates to be mounted on one chip has been increased in order to implement a device having more multifunctions. For this reason, it is hard to give access to an input/output terminal in a reduced cell and there is thus increased a possibility that a local wiring jam might be generated in each place. As a countermeasure to be taken against the problem, layout means has been disclosed in JP-A-2003-167934. FIG. 12(a) shows an example of the prior art disclosed in JP-A-2003-167934. In JP-A-2003-167934, a wiring jam portion is retrieved and a wiring cell 101 shown in FIG. 12(a) is then applied. The wiring cell 101 is separated from a core cell 102 for implementing a logic function and is constituted by only a power wiring portion. As shown in FIG. 12(b), furthermore, plural kinds of wiring cell groups having different cell heights are prepared for the wiring cell and are selected and replaced depending on the degree of the jam of the wiring between the cells. Consequently, the local wiring jam can be eliminated so that a chip size can be thus optimized.

However, a wide metal wiring is used for a power wiring cell shown in FIG. 12(a) in such a manner that a connection to a source voltage supply wiring in the core cell can be carried out by only the replacement of the power wiring portion. For this reason, there is a possibility that a short circuit with a wiring in the core cell might be carried out due to a slight shift of a finished shape at a step of processing a wide metal. Therefore, it can also be proposed that a metal interval causing no short circuit is previously applied to the metal wiring in the core cell. However, this reduces the degree of freedom of the wiring in the core cell.

In some cases in which the area of the power wiring cell is excessively large, moreover, a variation in etching or a wiring capacity is caused in a formation of a pattern. In some cases, therefore, an area ratio of the power wiring causes a problem of a variation in the wiring capacity in addition to the generation of a uniform pattern on a chip surface in the formation of the pattern.

### SUMMARY OF THE INVENTION

In consideration of the actual circumstances, the invention has been made and has an object to provide a semiconductor integrated circuit apparatus capable of enhancing precision in a pattern, reducing a variation in a wiring capacity and improving a degree of freedom of a wiring.

Moreover, it is an object of the invention to provide a semiconductor integrated circuit apparatus capable of giving a power wiring which is wide and has no possibility of a short circuit without reducing a degree of freedom of a wiring in a core cell on a chip surface.

Therefore, the invention provides a semiconductor integrated circuit apparatus comprising at least two power wirings provided in a first direction which is coincident with a direction of a cell train in a bock in which a logic cell is disposed and serving to supply a source voltage into the logic cell, wherein the power wiring has a slit at a regular interval in the first direction.

By the structure, it is possible to regulate an area of a power wiring cell by forming the slit. It is possible to prevent a variation in etching or a wiring capacity from being caused in a formation of a pattern. More specifically, it is possible to eliminate a problem of a short circuit due to a slight positional shift caused by an increase in a width of the wiring. Thus, it is possible to cause a pattern on a chip surface to be uniform in the formation of the pattern, and furthermore, to reduce the variation in the wiring capacity. Thus, it is possible to provide a desirable power wiring without reducing a degree of freedom of the wiring in a core cell.

According to the invention, in the semiconductor integrated circuit apparatus, the slit includes a comb-shaped slit which is arranged like a comb at a regular interval in the first direction.

By the structure, it is possible to provide a power wiring having no possibility of a shirt circuit which might be caused by an increase in a width without reducing a degree of freedom of the wiring in the core cell.

According to the invention, in the semiconductor integrated circuit apparatus, the power wiring includes a grid-shaped slit provided at a regular interval.

According to the invention, in the semiconductor integrated circuit apparatus, there are provided a core cell constituting a circuit function and a power wiring cell to be connected to the core cell and the logic cell is constituted, and a power supply wiring in the core cell is extended to a boundary portion between the power wiring cell and the core cell and the power wiring cell is constituted by a power wiring unit cell on a minimum unit including a slit in the vicinity of the boundary portion.

According to the invention, in the semiconductor integrated circuit apparatus, the power wiring unit cell constitutes a shape of T by combining a wiring arranged in the first direction corresponding to the direction of the cell train in the block in which the logic cell is disposed and a wiring extended in a second direction which is orthogonal to the first direction.

According to the invention, in the semiconductor integrated circuit apparatus, the power wiring unit cell is disposed adjacently at a regular interval in the first direction, thereby constituting a power wiring including a serial comb-shaped slit.

According to the invention, in the semiconductor integrated circuit apparatus, a position of an arrangement of a source voltage supply wiring in the core cell is preset into coordinates in the first direction with respect to the wiring in the second direction of the power wiring cell, thereby carrying out a connection to a metal wiring in the second direction of the power wiring.

According to the invention, in the semiconductor integrated circuit apparatus, a portion constituting the T shape of the power wiring cell is formed by an active region.

According to the invention, in the semiconductor integrated circuit apparatus, a portion constituting the T shape of the power wiring cell is formed by a metal and an active region.

According to the invention, in the semiconductor integrated circuit apparatus, the power wiring unit cell constitutes a shape of I by a wiring portion having a small width which is extended in a second direction that is perpendicular to the first direction and a wiring portion formed on both ends of the wiring portion and extended in the first direction.

According to the invention, in the semiconductor integrated circuit apparatus, the wiring portion is a metal or an active region.

According to the invention, in the semiconductor integrated circuit apparatus, at least one contact is disposed in a metal portion of the power wiring unit cell.

Moreover, the invention provides a method of designing a semiconductor integrated circuit apparatus in which a lower wiring cell and a core cell to be connected to the power wiring cell are disposed to constitute a logic cell, the apparatus including at least two power wirings provided in a first direction which is coincident with a direction of a cell train in a block in which the logic cell is disposed and serving to supply a source voltage into the logic cell in a boundary portion with the core cell, comprising the steps of:

preparing the power wiring cell in which the power wiring has a slit at a regular interval in the first direction; and arranging the power wiring cell corresponding to the core cell.

According to the invention, in the method of designing a semiconductor integrated circuit apparatus, the step of preparing the power wiring cell includes a step of preparing plural kinds of power wiring unit cells having at least two heights.

According to the invention, in the method of designing a semiconductor integrated circuit apparatus, the step of preparing the power wiring cell includes a step of preparing plural kinds of power wiring unit cells in which the power wiring portion extended in the first direction has at least one wiring width.

According to the invention, in the method of designing a semiconductor integrated circuit apparatus, the arranging step includes a step of causing a metal or an active region of the power wiring unit cell to form a band-shaped straight line in the first direction, and the power wiring cell and a source voltage supply wiring in the core cell are connected to each other in an automatic layout.

According to the invention, in the method of designing a semiconductor integrated circuit apparatus, the arranging step includes a step of connecting a terminal provided on a boundary between the power wiring cell and the core cell to the power wiring cell in the automatic layout in the source voltage supply wiring in the core cell.

According to the structure, it is possible to avoid a short circuit with the wiring in the core cell at the step of processing a wide metal which is caused in the case in which the height of the power wiring cell is increased and to maintain a wiring track between the cells without reducing a degree of freedom of the metal wiring in the core cell.

Moreover, the power wiring cell has the shape. Consequently, an area ratio of the metal wiring can be maintained and a pattern on a chip surface can be caused to be uniform.

### BRIEF DESCRIPTION OF THE DRAWINGS

FIG. 1 is a view showing a logic cell of a semiconductor integrated circuit apparatus according to a first embodiment of the invention,

FIG. 2 is a view showing a power wiring unit cell on a minimum unit constituting a power wiring cell in the logic cell,

FIG. 3 is a view showing a power wiring unit cell having different cell heights in the power wiring unit cell,

FIG. 4 is a view showing a structure of a power wiring unit cell according to a second embodiment of the invention,

FIG. 5 is a view showing a structure of the power wiring unit cell according to the embodiment,

FIG. 6 is a view showing a logic cell of a semiconductor integrated circuit apparatus according to a third embodiment of the invention,

FIG. 7 is a view showing a structure of a power wiring unit cell in the logic cell,

FIG. 8 is a view showing a power wiring unit cell having different cell heights in the power wiring unit cell,

FIG. 9 is a view showing a logic cell of a semiconductor integrated circuit apparatus according to a fourth embodiment of the invention,

FIG. 10 is a view showing a power wiring unit cell in the logic cell,

FIG. 11 is a view showing a power wiring unit cell having different cell heights in the power wiring unit cell, and

FIG. 12 is a view showing a semiconductor integrated circuit apparatus constituted by using the conventional art.

### DESCRIPTION OF THE PREFERRED EMBODIMENTS

A semiconductor integrated circuit apparatus according to an embodiment of the invention will be described below with reference to the drawings.

### First Embodiment

FIG. 1 shows an example of a structure of a semiconductor integrated circuit apparatus according to a first embodiment of the invention.

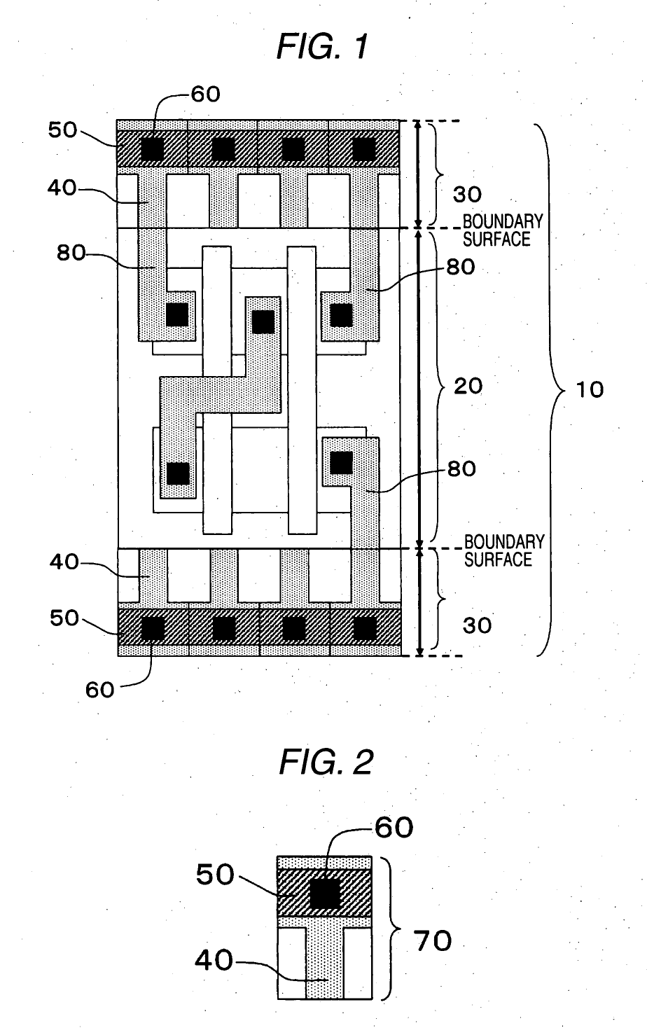

A logic cell 10 in FIG. 1 is formed by a core cell 20 constituting a circuit function (for example, an inverter, an AND, an NAND, an NOR, a latch and a flip-flop) and a power wiring cell 30 including a power wiring. The power wiring cell 30 is disposed on both sides of the core cell 20 without respective boundaries overlapping each other, and one of them supplies a source voltage and the other supplies a ground voltage. As shown in FIG. 2, the power wiring cell 30 is constituted by a power wiring unit cell 70 having a metal wiring 40, an active region 50 for holding an electric potential of a substrate to be constant, and a contact 60 for electrically connecting the metal wiring 40 to the active region 50. The metal wiring 40 takes a shape of T and the power wiring unit 70 is disposed adjacently on left and right so that a power wiring extended in a direction of a cell train in a chip can be formed. Furthermore, a wiring extended to a boundary of the power wiring unit cell in a perpendicular direction in the T-shaped metal 40 is connected to a metal wiring 80 extended to a cell boundary of the core cell 20 as shown in FIG. 1. Consequently, the source voltage can be supplied into the core cell 20.

FIG. 2 is a view showing the power wiring unit cell 70 including the T-shaped metal 40 to be used herein.

Description will be given to a method of carrying out a connection to the core cell 20 in the case in which the power wiring unit cell 70 shown in FIG. 2 is used. As described above, the metal wiring 80 in the core cell extended to the boundary between the power wiring cell 30 and the core cell 20 is set into coordinates in a horizontal direction in which a wiring extended in a perpendicular direction of the metal wiring 40 of the power wiring cell 30 is positioned so that it can be connected to the metal wiring 40. The reason is that the power wiring unit cell 70 is disposed adjacently and the wiring in the perpendicular direction of the metal wiring 40 is disposed at a regular interval. Moreover, the power wiring unit cell 70 is constituted by the metal wiring 40, the active region 50 for holding the electric potential of the substrate to be constant, and the contact 60 for electrically connecting the metal wiring 40 to the active region 50 as described above.

The T-shaped metal wiring 40 which is not connected to the metal wiring 80 in the core cell is present in the power wiring cell 30. On the assumption that the T-shaped metal wiring 40 is previously disposed to abut on the metal wiring in the core cell, a layout of the metal wiring in the core cell is carried out. Therefore, a minimum metal wiring interval rule can be prevented from being broken by the arrangement of the power wiring cell 30.

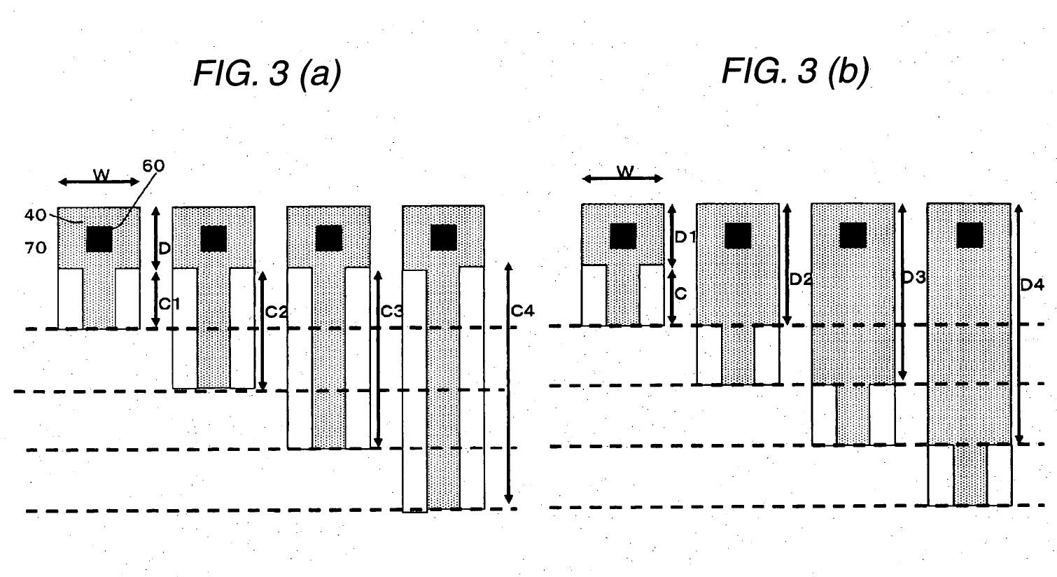

Moreover, it is also possible to use a plurality of cells having different heights for the power wiring unit cell 70 as shown in FIG. 3(a). For example, a wiring length of the wiring in the perpendicular direction of the T-shaped metal wiring 40 constituting the power wiring unit cell 70 is varied depending on the cell height. As shown in FIG. 1, in the power wiring unit cell 70 to be used in a certain cell train, at least one of the power wirings having the different cell heights shown in FIG. 3(a) is selected and disposed. Consequently, the number of wiring tracks between the cells in insufficient cells can be increased and a wiring efficiency in a chip can be enhanced without a decrease in a wiring resource of an upper layer. Referring to a method of selecting and disposing the power wiring unit cell, a designing method disclosed in JP-A-2003-167934 is taken as an example. By setting a width W and a height (length) D of a wide portion of the metal wiring 40 to be constant and varying lengths C1 to C4 in a narrow portion, the height of the cell is regulated.

Furthermore, it is also possible to change a region having a great wiring width in a horizontal direction of the metal wiring 40, that is, a wide portion depending on the height of the power wiring unit cell as shown in FIG. 3(b). By setting the width W of the wide portion and the length C of the narrow portion in the metal wiring 40 to be constant and varying heights (lengths) D1 to D4 of the wide portion, the height of the cell is regulated. Consequently, an area ratio of the metal wiring can be maintained and a pattern on a chip surface can be caused to be more uniform. Although the active region 50 for holding the electric potential of the substrate to be constant is omitted in the variants shown in FIGS. 3(a) and 3(b), it is desirable to form the active region 50 in a normal case.

As described above, the power wiring cell 30 is constituted by using the power wiring unit cell 70 utilizing the T-shaped metal wiring 40 and the coordinates of the arrangement of the metal wiring 80 in the core cell are set to be the coordinates in the horizontal direction in which the wiring extended in the perpendicular direction of the T-shaped metal wiring in the power wiring unit cell 70 is positioned. Consequently, it is not necessary to consider a short circuit with the wiring in the core cell (20) due to the wide power wiring (cell 30), and furthermore, it is possible to maintain the degree of freedom of the metal wiring 80 in the core cell and to enhance the number of the wiring tracks between the cells in the logic cell 10. By applying, to the power wiring unit cell 70, the metal shape of T having a ratio of the narrow and wide portions of the metal wiring 40 which is varied as shown in FIG. 3(b), it is possible to maintain the area ratio of the metal wiring 40 and to cause the pattern on the chip surface to be uniform.

### Second Embodiment

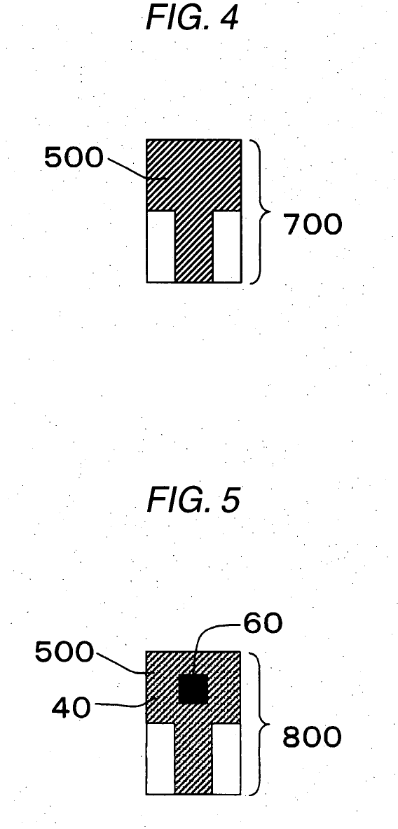

FIGS. 4 and 5 show an example of a structure of a semiconductor integrated circuit apparatus according to a second embodiment of the invention.

FIG. 4 shows a power wiring unit cell 700 constituted by only an active region 500 for holding an electric potential of a substrate to be constant.

Although the metal wiring 40 of the power wiring unit cell 70 takes the shape of T in the first embodiment, it is possible to form a power wiring extended in a direction of a cell train in a chip in the same manner as in the power wiring unit cell 70 by forming the T shape in the active region 500 and disposing the T shape adjacently on left and right in the power wiring unit cell 700 according to the embodiment.

In the case in which a metal wiring 80 in the core cell is formed by the active region, it is connected to a wiring extended in a perpendicular direction of the T-shaped active region of the power wiring unit cell 700 so that a power can be supplied into the core cell.

Next, FIG. 5 shows a power wiring unit cell 800 constituted by a T-shaped metal wiring 40, the T-shaped active region 500 and a contact 60 for electrically connecting the metal wiring 40 to the active region 500. By setting both a metal layer and the active region to take a T shape, the metal wiring 80 in the core cell is connected to the power wiring unit cell 800 also in the case in which it is formed by either the metal layer or the active region. Consequently, it is possible to supply a power into the core cell.

In the case in which the metal wiring 80 is formed by both the metal layer and the active region, moreover, it is possible to reduce a wiring resistance by compensating for a part corresponding to a reduction in a width of a metal by the active region. Furthermore, the shapes of the metal layer and the active region which constitute the power wiring unit cell may be the same or different from each other.

### Third Embodiment

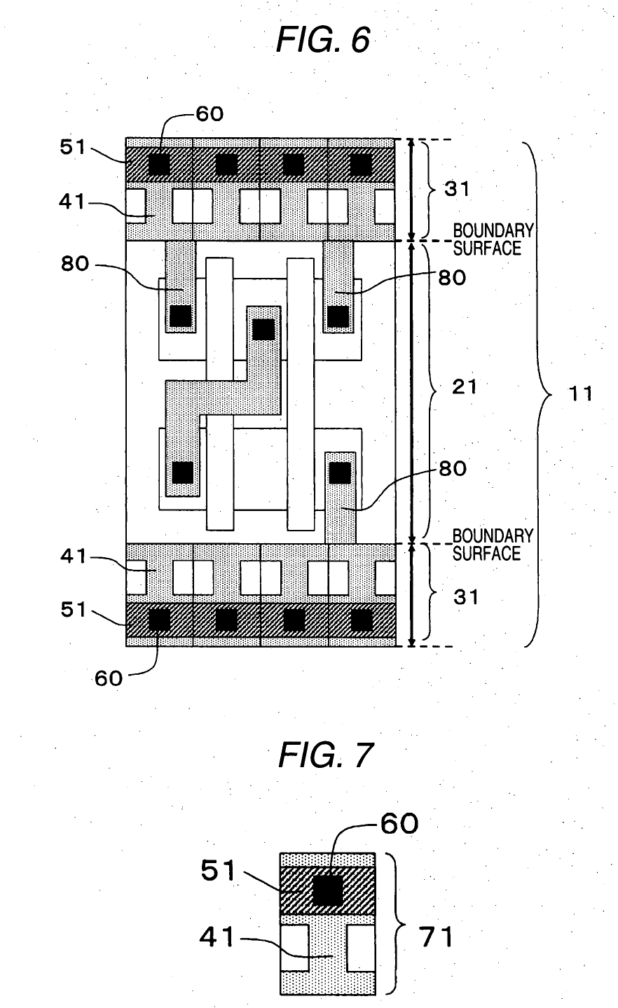

FIG. 6 shows an example of a structure of a semiconductor integrated circuit apparatus according to a third embodiment of the invention.

A logic cell 11 shown in FIG. 6 is constituted by a core cell 21 and a power wiring cell 31. The power wiring cell 31 is disposed on upper and lower parts of the core cell 21 without respective boundaries overlapping each other, and one of the power wiring cells 31 supplies a source voltage and the other supplies a ground voltage. As shown in FIG. 7, moreover, the power wiring cell 31 is constituted by a power wiring unit cell 71 having a metal wiring 41, an active region 51 for holding an electric potential of a substrate to be constant, and a contact 60 for electrically connecting the metal wiring 41 to the active region 51. By disposing the power wiring unit cell 71 adjacently on left and right, it is possible to form a power wiring extended in a direction of a cell train in a chip.

Although the power wiring unit cell 70 takes the metal shape of T in the first embodiment, the power wiring unit cell 71 according to the embodiment takes a metal shape of I. The metal shape of I is taken by metal wirings in a horizontal direction of upper and lower ends of the power wiring unit cell 71 and the metal wiring 41 having a component in a perpendicular direction which serves to connect them at a center of the power wiring unit cell 71.

Because of the I shape, when the power wiring unit cell 71 is disposed adjacently on left and right, two power wirings extended in the direction of the cell train are formed on upper and lower portions of the power wiring cell 31. One of the two power wirings which is provided on the core cell side is connected to a metal wiring 80 in the core cell. In other words, it is not necessary to preset coordinates in a horizontal direction of the metal wiring 80 in the core cell and it is possible to enhance a degree of freedom of the wiring in the core cell.

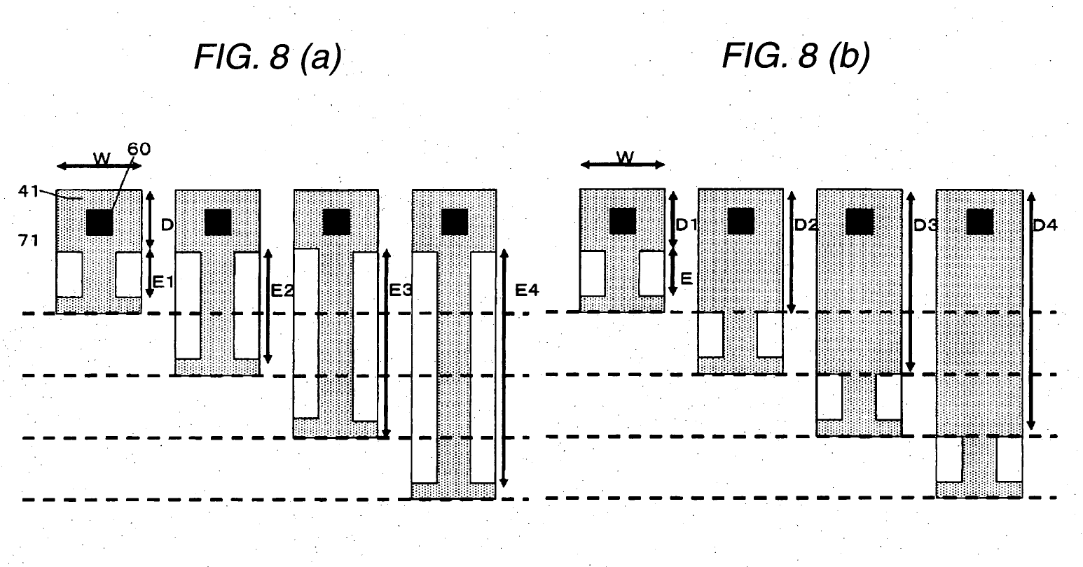

In the same manner as in the first embodiment, moreover, a plurality of cells having different heights shown in FIG. 8(a) is present and a wiring length of a wiring extended in the perpendicular direction at the center of the I-shaped metal 41 constituting the power wiring unit cell 71 is varied depending on the cell height. By setting a width W and a height (length) D of a wide portion in the metal wiring 41 to be constant and varying lengths E1 to E4 of a narrow portion, the cell height is regulated.

As shown in FIG. 6, referring to the power wiring unit cell 71 to be used in a certain cell train, at least one of the power wirings having different cell heights is selected and disposed. Consequently, it is possible to increase the number of wiring tracks between the cells in the insufficient cells and to enhance a wiring efficiency in the chip without a decrease in a wiring resource of an upper layer.

Furthermore, it is possible to change a region having a great wiring width in a horizontal direction of the metal 41, that is, a wide portion depending on the height of the power wiring unit cell as shown in FIG. 8(b). By setting the width W of the wide portion and the length E of the narrow portion in the metal wiring 41 to be constant and varying heights (lengths) D1 to D4 of the wide portion, the height of the cell is regulated. Consequently, an area ratio of the metal wiring can be maintained and a pattern on a chip surface can be caused to be more uniform.

In the same manner as in the second embodiment, moreover, the power wiring unit cell 71 is constituted by the active region. Even if the metal wiring 80 in the core cell is formed by either the metal layer or the active region, therefore, it can be connected to the power wiring unit cell 71 so that a power can be supplied into the core cell.

### Fourth Embodiment

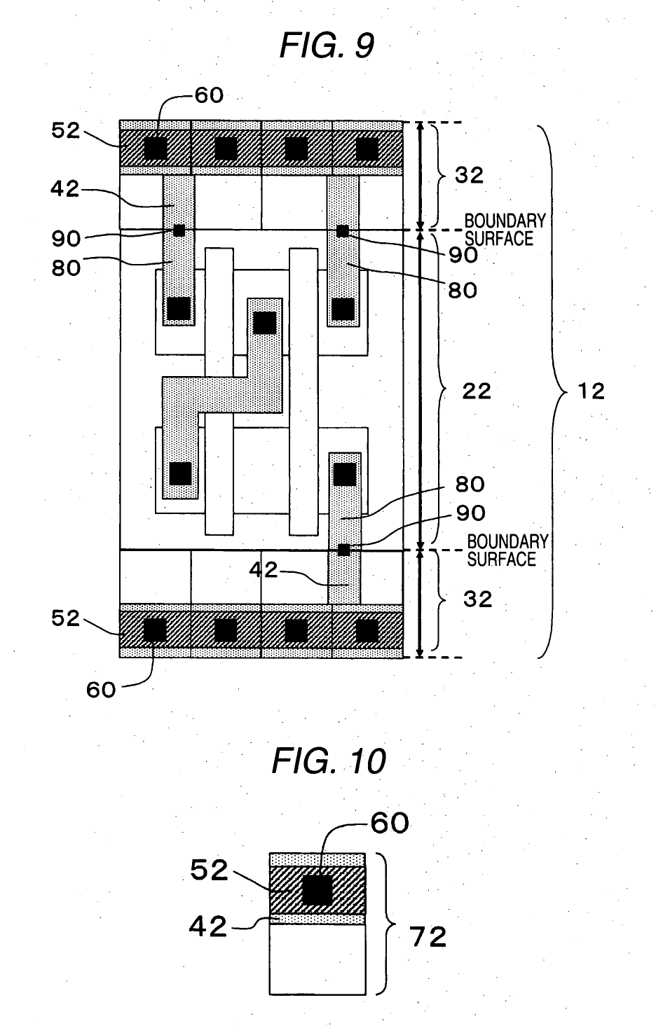

FIG. 9 shows an example of a structure of a semiconductor integrated circuit apparatus according to a fourth embodiment of the invention.

A logic cell 12 shown in FIG. 9 is constituted by a core cell 22 and a power wiring cell 32. The power wiring cell 32 is disposed on upper and lower parts of the core cell 22 without respective boundaries overlapping each other, and one of them supplies a source voltage and the other supplies a ground voltage. As shown in FIG. 10, moreover, the power wiring cell 32 is constituted by a power wiring unit cell 72 having a metal wiring 42, an active region 52 for holding an electric potential of a substrate to be constant, and a contact 60 for electrically connecting the metal wiring 42 to the active region 52. By disposing the power wiring unit cell 72 adjacently on left and right, it is possible to form a power wiring extended in a direction of a cell train in a chip.

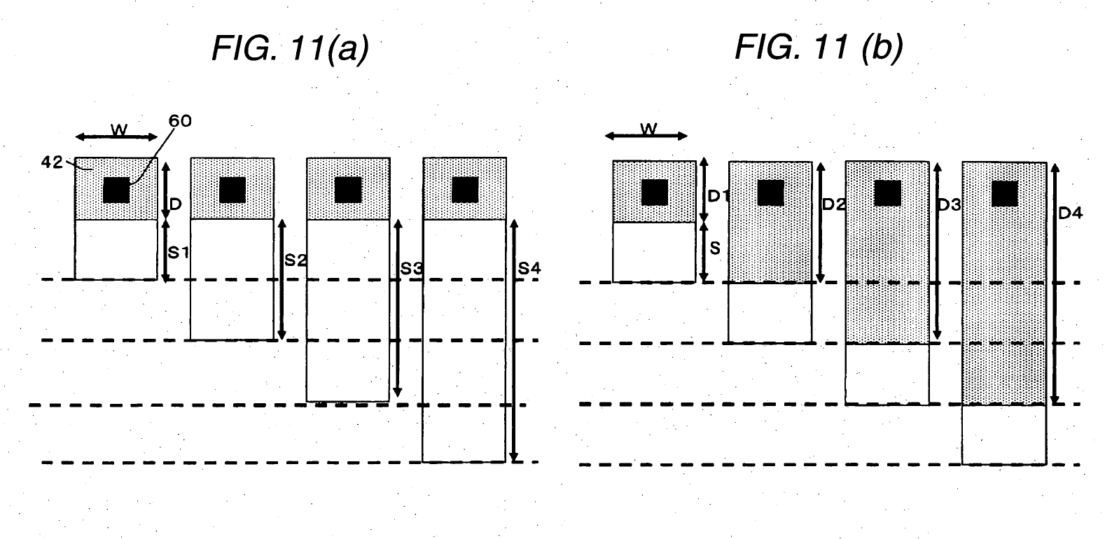

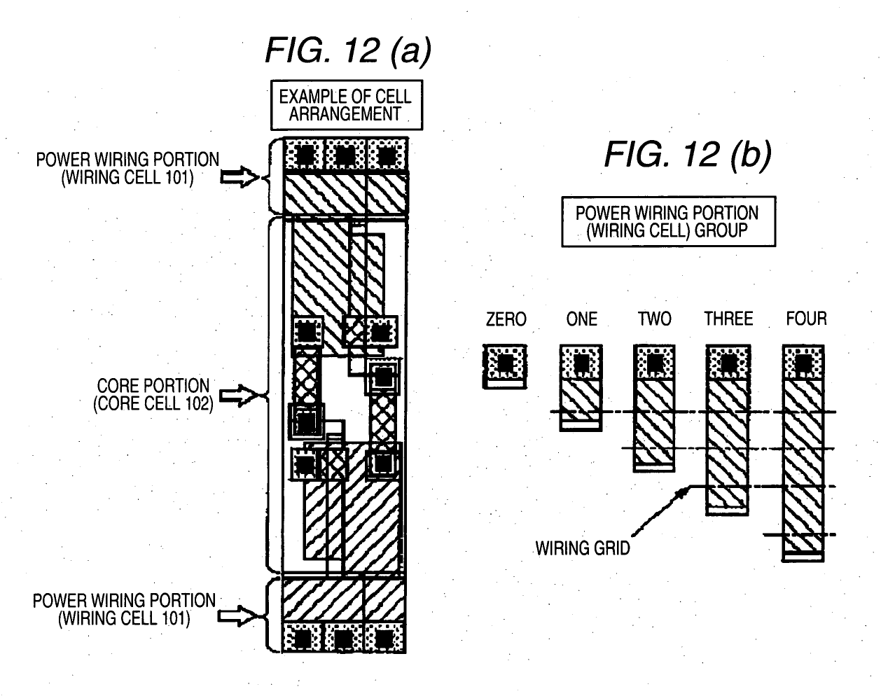

In the same manner as the metal wiring 40 taking the T shape according to the first embodiment, the power wiring unit cell 72 according to the embodiment has no metal wiring in a perpendicular direction. In other words, the T shape is not constituted but the band-shaped metal wiring 42 is provided. Description will be given to a connecting method to the core cell 22 in the case in which the power wiring unit cell 72 in FIG. 10 is used. As shown in FIG. 9, a power accessing terminal 90 is disposed in a portion in which a metal wiring 80 crosses a boundary between the power wiring cell 32 and the core cell 22. In an automatic wiring for the cell, next, the power accessing terminal 90 is connected to the power wiring cell 32. Preferably, at least one of the power wiring unit cells having different heights shown in FIG. 11(a) is selected depending on the number of insufficient wiring tracks between the cells and the power wiring unit cell is automatically disposed in the same manner as in the first embodiment. At the same time, the power accessing terminal 90 on the core cell boundary is retrieved and is connected to the power wiring unit cell in a perpendicular direction from the power accessing terminal 90 when it is detected. By setting a width W and a height (length) D of the metal wiring 42 to be constant and varying lengths s1 to s4 of the metal wiring 80 passing through the portion crossing the boundary between the power wiring cell 32 and the core cell 22, a regulation is carried out.

Furthermore, it is possible to vary a wiring width in a horizontal direction of the metal 42 depending on the height of the power wiring unit cell as shown in FIG. 11(b). Consequently, an area ratio of the metal wiring can be maintained and a pattern on a chip surface can be caused to be more uniform. By setting a width W of a wide portion of a metal wiring 41 and the length s of the metal wiring 80 to be constant and varying heights (lengths) D1 to D4 of the wide portion, the height of the cell is regulated. Consequently, an area ratio of the metal wiring can be maintained and the pattern on the chip surface can be caused to be more uniform.

In the same manner as in the second embodiment, moreover, the power wiring unit cell 72 is constituted by the active region. Even if the metal wiring 80 in the core cell is formed by either the metal layer or the active region, therefore, it can be connected to the power wiring unit cell 72 so that a source voltage can be supplied into the core cell.

By employing the structure and the designing method, it is possible to maintain a degree of freedom of the metal wiring in the core cell and to enhance the wiring track between the cells in the logic cell 12, and furthermore, to ensure an area ratio of the metal wiring and to cause the pattern on the chip surface to be uniform.

As described above, the invention relates to a semiconductor integrated circuit apparatus. In particular, the shape of the power wiring cell in the logic cell is set as described above. Consequently, the power metal wiring can be prevented from having a great width and the wiring track between the cells in the logic cell can be maintained without a reduction in the degree of freedom of the metal wiring in the core cell. Furthermore, the area ratio of the metal wiring can be maintained and the pattern on the chip surface can be caused to be uniform. Therefore, the invention is useful for a semiconductor integrated circuit apparatus comprising a plurality of logic cells.

What is claimed is:

1. A semiconductor integrated circuit apparatus, comprising:
at least two power wirings provided in a first direction which is coincident with a direction of a cell train in a block in which a logic cell is disposed and serving to supply a source voltage into the logic cell;
wherein the power wiring has a slit at a regular interval in the first direction.

2. The semiconductor integrated circuit apparatus according to claim 1, wherein the slit takes a shape of a comb in which it is arranged like a comb at a regular interval in the first direction.

3. The semiconductor integrated circuit apparatus according to claim 1, wherein the slit takes a shape of a grid.

4. The semiconductor integrated circuit apparatus according to claim 1, further comprising:
a core cell constituting a circuit function and a power wiring cell to be connected to the core cell, and constituting the logic cell;
wherein a power supply wiring in the core cell is extended to a boundary portion between the power wiring cell and the core cell; and
the power wiring cell is constituted by a power wiring unit cell on a minimum unit including a slit in the vicinity of the boundary portion.

5. The semiconductor integrated circuit apparatus according to claim 4, wherein the power wiring unit cell constitutes a shape of T by combining a wiring arranged in the first direction corresponding to the direction of the cell train in the block in which the logic cell is disposed and a wiring extended in a second direction which is orthogonal to the first direction.

6. The semiconductor integrated circuit apparatus according to claim 5, wherein the power wiring unit cell is disposed adjacently at a regular interval in the first direction, thereby constituting a power wiring including a serial comb-shaped slit.

7. The semiconductor integrated circuit apparatus according to claim 5, wherein a position of an arrangement of a source voltage supply wiring in the core cell is preset into coordinates in the first direction with respect to the wiring in the second direction of the power wiring cell, thereby carrying out a connection to a metal wiring in the second direction of the power wiring.

8. The semiconductor integrated circuit apparatus according to claim 5, wherein a portion constituting the T shape of the power wiring cell is formed by an active region.

9. The semiconductor integrated circuit apparatus according to claim 5, wherein a portion constituting the T shape of the power wiring cell is formed by a metal and an active region.

10. The semiconductor integrated circuit apparatus according to claim 4, wherein the power wiring unit cell constitutes a shape of I by a wiring portion having a small width which is extended in a second direction that is perpendicular to the first direction and a wiring portion formed on both ends of the wiring portion and extended in the first direction.

11. The semiconductor integrated circuit apparatus according to claim 10, wherein the wiring portion is a metal or an active region.

12. The semiconductor integrated circuit apparatus according to claim 1, wherein at least one contact is disposed in a metal portion of the power wiring unit cell.

13. A method of designing a semiconductor integrated circuit apparatus in which a power wiring cell and a core cell to be connected to the power wiring cell are disposed to constitute a logic cell,
the apparatus including at least two power wirings provided in a first direction which is coincident with a direction of a cell train in a block in which the logic cell is disposed and serving to supply a source voltage into the logic cell in a boundary portion with the core cell, comprising the steps of:
preparing the power wiring cell in which the power wiring has a slit at a regular interval in the first direction; and
arranging the power wiring cell corresponding to the core cell.

14. The method of designing a semiconductor integrated circuit apparatus according to claim 13, wherein the step of preparing the power wiring cell includes a step of preparing plural kinds of power wiring units cells having at least two heights.

15. The method of designing a semiconductor integrated circuit apparatus according to claim 13, wherein the step of preparing the power wiring cell includes a step of preparing plural kinds of power wiring unit cells in which the power wiring portion extended in the first direction has at least one wiring width.

16. The method of designing a semiconductor integrated circuit apparatus according to claim 13, wherein the arranging step includes a step of causing a metal or an active region of the power wiring unit cell to form a band-shaped straight line in the first direction, and the power wiring cell and a source voltage supply wiring in the core cell are connected to each other in an automatic layout.

17. The method of designing a semiconductor integrated circuit apparatus according to claim 13, wherein the arranging step includes a step of connecting a terminal provided on a boundary between the power wiring cell and the core cell to the power wiring cell in the automatic layout in the source voltage supply wiring in the core cell.
